(19) United States
(12) Patent Application Publication
(10) Pub. No.: US 2015/0357193 A1
(43) Pub. Date: Dec. 10, 2015

(54) METHOD FOR PRODUCING AN EPITAXIAL SEMICONDUCTOR LAYER

(71) Applicant: FRAUNHOFER-GES. ZUR FÖRDERUNG DER ANGEWANDTEN FORSCHUNG E.V., München (DE)

(72) Inventors: Dietmar Temmler, Dresden (DE); Volker Kirchhoff, Wehlen (DE); Christoph Metzner, Dresden (DE); Jens-Peter Heinß, Dresden (DE)

(21) Appl. No.: 14/760,601

(22) PCT Filed: Oct. 17, 2013
(86) PCT No.: PCT/EP2013/071752

§ 371 Date: Jul. 13, 2015

(30) Foreign Application Priority Data
Jan. 30, 2013 (DE) 10 2013 201 510.0

(51) Int. Cl. H01L 21/02; H01L 21/3065

(52) U.S. Cl. CPC H01L 21/02689; H01L 21/02381; H01L 21/0242; H01L 21/02428; H01L 21/02532; H01L 21/02592; H01L 21/02631; H01L 21/02658; H01L 21/3065

(57) ABSTRACT

A method for producing an epitaxial layer made of a semiconductor material is provided in which at least one surface region of a monocrystalline substrate is subjected to dry etching inside a work chamber. A non-epitaxial semiconductor layer is then deposited on the etched surface region of the monocrystalline substrate by vaporizing a semiconductor material using an electron beam, as a result of which vapour particles of the vaporized semiconductor material are deposited on the etched surface region of the monocrystalline substrate. The non-epitaxial semiconductor layer is finally crystallized by inputting energy.

### CROSS-REFERENCE TO RELATED APPLICATIONS

This application is a national stage entry of International Patent Application PCT/EP2013/071752, filed Oct. 17, 2013, entitled “METHOD FOR PRODUCING AN EPITAXIAL SEMICONDUCTOR LAYER,” the entire contents of which are incorporated by reference, which in turn claims priority to German patent application DE 10 2013 201 510.0, filed Jan. 30, 2013, entitled “Verfahren zum Herstellen einer epitaktischen Halbleiterschicht”, the entire contents of which are incorporated by reference.

### TECHNICAL FIELD

The invention relates to a method for producing an epitaxial semiconductor layer using electron beam technology for microelectronic, photovoltaic, sensory, and micromechanical applications. In the sense of the invention, the term “an epitaxial layer” refers to that type of monocrystalline layers wherein at least the crystallographic orientation of the surface of a growing crystal corresponds to the orientation of the surface of a monocrystalline substrate.

### BACKGROUND

Various methods for producing epitaxial semiconductor layers are known. The industrial production of epitaxial semiconductor layers on a monocrystalline substrate for the above-mentioned applications has been based up to now almost exclusively on thermally activated epitaxial layer growth by CVD processes.

Thus, for example, in the chemical gas phase epitaxy of silicon layers, monocrystalline silicon wafers are initially heated in a process chamber to a temperature of 600° C. to 1200° C. Subsequently, silicon-containing compounds, such as, for example, silanes, are usually inserted into the process chamber in a mixture including hydrogen, which causes the decomposing of the silicon-containing compound. Liberated silicon atoms then deposit on the surface of the silicon wafers, first forming a closed layer and subsequently growing in the layer thickness. During the growth of the crystalline structure, the monocrystalline layer structure of the silicon wafers is acquired and continued. A disadvantage of this method is that the crystal growth is strongly temperature-dependent. Thus, industry-relevant growth rates are only achieved at substrate temperatures above 800° C. At high temperatures, there is the negative effect that doping elements diffuse out of the surface regions of such a semiconductor layer or of the substrate, which leads to losses in quality. With this epitaxy method, a compromise with respect to the deposition temperature must therefore often be made between the deposition rate and the layer quality. Furthermore, so-called liquid phase epitaxy methods are known, wherein a semiconductor material is dissolved in a solvent to below its melting point, and subsequently the saturated melt is applied in a hydrogen atmosphere to a crystalline substrate on which the semiconductor material then also grows in a crystalline manner. The technical implementation can only be realized at a very high expense, since the process parameters to be observed here have only very small tolerances. Therefore these methods have as yet not been used industrially.

### BRIEF DESCRIPTION OF DRAWINGS

The embodiments may be better understood with reference to the following drawing and description.

FIG. 1 illustrates a flow diagram of a process for producing an epitaxial semiconductor layer.

### DETAILED DESCRIPTION

The technical problem of the invention is therefore to provide a method by means of which the disadvantages from the prior art can be overcome. In particular, using the inventive method, it should be possible to manufacture high-quality epitaxial semiconductor layers with high deposition rates.

As the basis for carrying out the inventive method, a monocrystalline substrate is used on whose surface an epitaxial semiconductor layer is formed at least in a surface region (which is preferentially a flat surface region). For example, monocrystalline silicon- or sapphire-substrates are suitable as a substrate. These monocrystalline substrates are preferentially configured wafer-shaped. In a first process step, at least the surface region of the monocrystalline substrate, on which the monocrystalline semiconductor layer is to be configured later, is subjected to a cleaning in which both any foreign and contamination layers, and also a few, but at least one atomic layer of the substrate material are etched from the substrate surface. In-situ dry-etching processes are suitable therefor.

A process of electron beam-supported gas phase etching is preferentially used for the cleaning of the substrate surface. In this case, the substrate to be cleaned is introduced into a work chamber into which an etching gas is introduced. Subsequently the surface of the monocrystalline substrate to be cleaned is completely swept by the electron beam at a very high deflection frequency [of the electron beam]. The gas introduced into the work chamber develops an etching effect on the substrate surface only under the influence of the electron beam in the regions on which the beam impacts. For example, the gases SF₆, CF₄, CHF₃, or XeF₂ are suitable for the electron beam-supported gas phase etching, of which gases at least one gas is introduced into the work chamber. In the inventive method, electron beam-supported gas phase etching is particularly suited for the cleaning of the monocrystalline substrate because, on the one hand, damage to the substrate and a contamination of the substrate by foreign material particles is thereby prevented, and, on the other hand, subsequent process steps are also carried out using electron beam processes, which makes possible similar system arrangements and similar process conditions in the work chamber and/or in the work chambers of the individual process steps.

In a second process step, a non-epitaxial layer made of a semiconductor material is deposited on the cleaned surface region of the monocrystalline substrate. Here, the non-epitaxial layer is preferentially configured as an amorphous layer. The deposition of the non-epitaxial layer is effected using electron beam evaporation, i.e., the semiconductor material, preferentially silicon-containing semiconductor material, is heated with an electron beam and finally evaporated, wherein vapor particles of the evaporated semiconductor material deposit on the cleaned surface region of the monocrystalline substrate. It is known that during the electron-beam evaporation, a substrate to be evaporated is subjected to a substantially lower thermal load (approximately at most 200° C.) than in processes wherein an epitaxial semiconductor layer is deposited using CVD methods (epitaxy methods) known from the prior art. In contrast, the inventive deposition of a non-epitaxial semiconductor layer is therefore also referred to as cold layer deposition. This can preferably occur at a deposition rate >1 μm/min.

In order to receive as little contamination by foreign particles as possible in the deposited semiconductor layer it is advantageous, if the semiconductor material is evaporated in a containerless manner. For the same reason it is also possible to subject the semiconductor material to a cleaning process prior to the evaporation. Thus, for example, the semiconductor material can be pre-cleaned using an in-situ cleaning distillation cycle. For this purpose, the electron beam evaporator is configured, for example, as an axial electron beam gun with electromagnetic beam guiding at a high scanning frequency (>50 kHz). By means of a programmed scan pattern of the electron beam and an adjustable beam power, regions of the starting material (for example a silicon ingot) to be evaporated can be selectively melted, the impurities concentrated in the molten pool (lateral zone cleaning), and then evaporated against a collecting panel. What remains is an even purer starting material for the electron beam evaporation, with which it is possible to deposit a high-purity non-epitaxial semiconductor layer, which is preferentially configured amorphous.

As already described above, the deposition of silicon layers is especially suited for this method. Here, the silicon to be evaporated and to be deposited can be both pure silicon as well as silicon doped with other elements. It is, however, also possible to dope the material to be evaporated only during the evaporation process by, for example, introducing a gas or aerosol containing the doping element into the work chamber during the evaporation process.

In a third process step of the inventive method, the non-epitaxial semiconductor layer is crystallized such that it is converted into an epitaxial semiconductor layer. The epitaxial crystallization of the non-epitaxial semiconductor layer is carried out by an energy input into the non-epitaxial semiconductor layer. This energy input can be realized, for example, using a laser beam, a quartz lamp device, or another energy beam source. The inventive crystallization of a non-epitaxial semiconductor layer is preferably effected using an electron beam technology wherein the non-epitaxial semiconductor layer is impinged by accelerated electrons of an electron beam. This can be realized, for example, by the entire surface of the non-epitaxial semiconductor layer being linearly swept from a lateral edge of the surface to the opposing lateral edge of the surface using a high-frequency (greater than 50 kHz) deflected, focused electron beam of an axial emitter. Thus, if the electron beam is, for example, linearly deflected from top to bottom and back again, starting, for example, at the left edge of the semiconductor layer surface, then after a number of traces, or even after each trace, the electron beam is gradually displaced in the direction of the right edge of the semiconductor layer surface until the entire surface of the semiconductor layer is swept by the electron beam. The energy input deposited in the semiconductor layer by the electron beam effects a crystallization of the semiconductor layer. If the entire surface of the semiconductor layer is swept by the electron beam with a suitable setting of the electron beam power, the scanning speed, and advance, an epitaxial semiconductor layer will be available.

It is to be noted that the advance speed at which the linearly deflected electron beam is displaced step-by-step over the entire surface of the semiconductor layer is associated with the speed of crystallization of the semiconductor layer. The optimal advance speed can be determined for each application in laboratory tests. In such laboratory tests, it can also prove advantageous to change the advance speed during the crystallization process of a semiconductor layer.

It is known that the penetration depth of an electron beam into a material, among other things, is also dependent on the acceleration voltage. The penetration depth of an electron beam into a material can therefore be set using this beam parameter. In the inventive method, the penetration depth of the electron beam during the crystallization of the non-epitaxial semiconductor layer is set such that it extends only slightly into the substrate and that the energy of the electron beam is absorbed as completely as possible by the semiconductor layer. This causes, on the one hand, an energy-saving process control, and, on the other hand, prevents a possible damage to the substrate.

The inventive method has a number of advantages. Due to the electron beam evaporating process it makes possible high deposition rates, which are substantially above the rates that are achieved in the prior art for high-purity layer depositions by CVD and sputtering methods. Therefore, substantially greater layer thicknesses (>5 μm) for an epitaxial semiconductor layer can be economically produced by means of the inventive method. The purity of the source material used is further increased by a possibly integrated cleaning cycle before the layer deposition, whereby epitaxy layers of extreme purity and thus of the highest crystal quality can be produced. The purity of the layer-substrate interface, a necessary condition for a high epitaxy quality, is ensured by the special in-situ dry etching process directly before the layer deposition. Due to the separation of the deposition of the semiconductor layer and the epitaxial crystallization, the crystallization is carried out with a minimum temperature budget by using the depth selectivity of the electron-beam energy input. The formation of defects in the layer-substrate arrangement is thereby largely prevented. A further advantage of the inventive method is that in all three process steps, electron beam technologies having identical or at least similar system configurations, and process conditions can be used inside the work chambers in which the process steps are carried out, which is advantageous for the design of devices for carrying out the inventive method. If, for example, the three process steps are carried out in separate, consecutively arranged modules, expensive port devices between the modules can be omitted. Alternatively, however, it is also possible to carry out two or even all process steps in one and the same work chamber under respectively suitable process conditions.

In a further embodiment of the inventive method, the epitaxial crystallized semiconductor layer is removed again from the substrate in an additional process step. In this way, a separate semiconductor monocrystal can be produced and the substrate again supplied with a coating.

An advantageous process step for removing the epitaxial semiconductor layer from the substrate is once again based on an electron beam technology. In this case, however, an electron beam is used at a different penetration depth than during the crystallization of the non-epitaxial semiconductor layer. Upon removal of the epitaxial semiconductor layer from the substrate, the penetration depth of the electron beam is set such that the maximum possible energy input occurs in the plane which forms the edge surface between the substrate and the epitaxial semiconductor layer. As already described above, it is known that the penetration depth of an electron beam depends on its acceleration voltage, and, accordingly, a required penetration depth of an electron beam can be set for splitting the epitaxial semiconductor layer from the monocrystalline substrate.

Just as with the crystallization of the non-epitaxial semiconductor layer, the removal of the epitaxial semiconductor layer takes place from a lateral edge of the semiconductor layer surface to the opposing lateral edge. That is, the surface of the epitaxial semiconductor layer is scanned using a focused electron beam of an axial electron beam gun with high frequency (>50 kHz) electromagnetic beam guiding programmed with an optimized temporal spatial beam guiding pattern from one edge of the semiconductor-layer surface to the opposing edge. The scanning direction of the electron beam, the advance in the direction of the successive layer removal, and the beam energy are optimally set to the specified substrate-semiconductor arrangement and the thickness of the epitaxial semiconductor layer in order to gently remove, i.e., without generating defects, the epitaxial semiconductor layer from the monocrystalline substrate by slight mechanical stress, which is, however, sufficient for the removal process, and with a low temperature budget close to the necessary minimum.

The deposition of the electron beam energy into the plane of the transition from the substrate to the epitaxial semiconductor layer in this case takes advantage of the fact that the energy density distribution of an electronic beam in the depth has a clear maximum at approximately one third of the penetration depth of the electrons. The depth of the energy density maximum is uniquely determined by the material thickness of the substrate-semiconductor layer arrangement and the acceleration voltage of the electron beam.

For the sake of completeness it should be mentioned that electron beam deflection controls are known for generating suitable deflection patterns for the crystallization of a non-epitaxial semiconductor layer or for removing an epitaxial semiconductor layer from the substrate.

### Exemplary Embodiment

The present invention is explained in more detail below by reference to an exemplary embodiment.

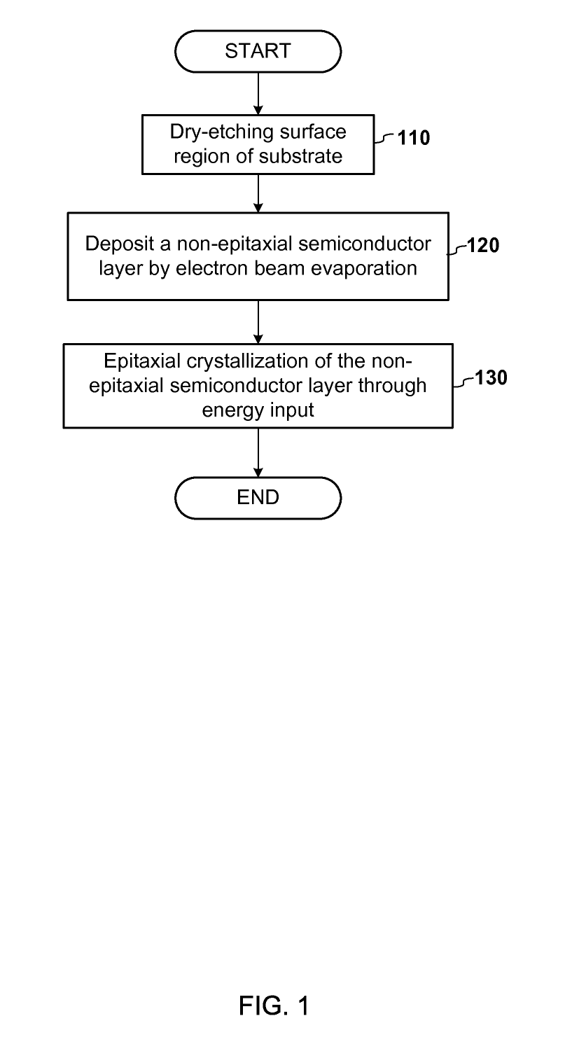

Three steps of a method for producing an epitaxial semiconductor layer are illustrated in FIG. 1. In a first step (110), a surface region of a monocrystalline substrate is dry etched. In a second step (120), a non-epitaxial semiconductor layer is deposited on the etched surface region of the monocrystalline substrate by a semiconductor material being evaporated using an electron beam. In a third step (130), epitaxial crystallization of the non-epitaxial semiconductor layer is caused by applying an energy input into the non-epitaxial semiconductor layer.

A 5-μm thick monocrystalline silicon layer is to be formed on one side of a 725-μm thick, disc-shaped and monocrystalline silicon substrate. According to a known wet-chemical ex-situ RCA cleaning of the p-doped silicon epitaxy substrate, it is introduced into a first high-vacuum station (base pressure ≦10⁻⁶ mbar) and freed there from the residual foreign and contamination layers by means of a cold in-situ gas phase etching. In this case, approx. 2 nm silicon is etched from one side of the substrate surface at the same time. The in-situ gas etching is configured as a special electron beam-supported gas phase etching process. The axial emitter for generating an electron beam is only driven with a low power <50 W and an acceleration voltage <1 keV in order to achieve the intended silicon removal and simultaneously prevent a permanent damage to the epitaxial substrate. High-purity XeF₂ is introduced into the high vacuum chamber as an etching gas. The etching of the silicon substrate is triggered by the surface of the silicon wafer to be etched being successively swept in a full-surface manner by the electron beam. In the regions in which the electron beam respectively impacts on the substrate surface, the etching gas is excited by the energy of the electron beam and exerts an etching action on the substrate surface.

Subsequently, the cleaned epitaxial substrate is transferred without vacuum interruption into a further high vacuum station for electron beam evaporation. The electron beam evaporating assembly is configured specially for the deposition of high-purity layers, on the one hand, since it is containerless, and, on the other hand, since prior to the actual evaporating the 7N high-purity silicon source material is additionally precleaned by the electron beam gun in a special in-situ cleaning distillation cycle. For this purpose, the electron beam evaporator is configured as an axial electron beam gun with electromagnetic beam guiding at a high scanning frequency (>50 kHz). Regions of a silicon ingot, which is used as an evaporation source material, are locally melted with a lower power electron beam by means of a programmed scan pattern, without the silicon ingot being substantially evaporated in the process. By successively displacing the local melt region on the surface of the silicon ingot, the impurities are concentrated in the molten pool. Such a process is also called lateral zone cleaning. After the zone cleaning of the silicon ingot, the part of the molten pool in which the impurities have collected is evaporated against a collecting panel using a moderate power electron beam. A high-purity silicon ingot remains, which is subsequently used for evaporating a silicon layer onto the cleaned silicon substrate.

The actual electron beam evaporation process onto the epitaxy substrate follows at a high deposition rate of 1 μm/min at a residual gas pressure of ≦10⁶ mbar. After the deposition, the cold-deposited silicon semiconductor layer (<200° C.) is amorphous.

In a final process step, the amorphous 5-μm thick silicon layer is converted into an epitaxial and thus monocrystalline silicon layer by the crystalline structure of the monocrystalline substrate surface being transferred to the deposited amorphous silicon semiconductor layer. The process is effected according to the invention by scanning the surface of the amorphous silicon layer using a focused electron beam of an axial electron beam gun with electromagnetic beam guiding at a high frequency (>50 kHz) with programmed power and with an optimized temporal spatial beam guiding pattern. The beam parameters used here were previously determined in a laboratory test and set such that the electron beam has a penetration depth of 5 μm so that the energy of the electron beam is nearly completely absorbed within the deposited silicon layer.

The crystallization process is guided starting from a lateral edge of the silicon layer over the entire surface of the silicon layer. In this process, the electron beam scans parallel to the crystallization front. Here the advance of the electron beam scan towards the advancing crystallization front is set to the optimal speed of the crystallization process determined by the material parameters of the layer-substrate arrangement, which was also previously determined in a laboratory test. After the completion of the scan with the electron beam, the formerly amorphous silicon layer is converted into a monocrystalline structure.

1. A method for producing an epitaxial layer from a semiconductor material, comprising:
dry-etching at least one surface region of a monocrystalline substrate inside a work chamber;
depositing a non-epitaxial semiconductor layer on the etched at least one surface region of the monocrystalline substrate by a semiconductor material being evaporated using an electron beam, whereby vapor particles of the evaporated semiconductor material precipitate on the etched at least one surface region of the monocrystalline substrate; and
causing epitaxial crystallization of the non-epitaxial semiconductor layer by applying an energy input into the non-epitaxial semiconductor layer.

2. The method according to claim 1, wherein the applying the energy input into the non-epitaxial semiconductor layer comprises impinging the non-epitaxial semiconductor layer by accelerated electrons of an electron beam.

3. A method according to claim 1, wherein a silicon or sapphire substrate is used as the monocrystalline substrate.

4. The method according to claim 1, wherein the dry-etching comprises electron beam-supported gas phase etching.

5. The method according to claim 4, wherein at least one of gases SF₆, CF₄, CHF₃, or XeF₂ is introduced into the work chamber.

6. The method according to claim 1, wherein silicon is used as the semiconductor material to be evaporated.

7. The method according to claim 1, wherein the semiconductor material is evaporated in a containerless manner.

8. The method according to claim 1, wherein the semiconductor material is cleaned before the electron beam evaporation.

9. The method according to claim 1, wherein the electron beam is an electron beam of an axial emitter, wherein a surface of the non-epitaxial semiconductor layer is swept at a scanning frequency of at least 50 kHz by the electron beam of the axial emitter.

10. The method according to claim 1, wherein an entire surface of the non-epitaxial semiconductor layer is linearly swept from one side of the entire surface to the opposing side of the entire surface.

11. The method according to claim 1, wherein after the epitaxial crystallization of the non-epitaxial semiconductor layer, the epitaxial semiconductor layer is removed from the monocrystalline substrate.

12. The method according to claim 11, wherein a surface of the epitaxially crystallized semiconductor layer is swept by an electron beam of an axial emitter at a scanning frequency of at least 50 kHz, wherein penetration depth of the electron beam is set such that a maximum of the energy input of the electron beam is located at an interface between the monocrystalline substrate and the semiconductor layer.
